(19) United States
(12) Patent Application Publication
(10) Pub. No.: US 2023/0150882 A1
(43) Pub. Date: May 18, 2023

(54) DIELECTRIC FOR ELECTROSTATIC CHUCK

(71) Applicant: KROSAKIHARIMA CORPORATION, Fukuoka (JP)

(72) Inventor: Kensaku HATTORI, Fukuoka (JP)

(73) Assignee: KROSAKIHARIMA CORPORATION, Fukuoka (JP)

(21) Appl. No.: 17/917,126

(22) PCT Filed: May 20, 2021
(86) PCT No.: PCT/JP2021/019183

§ 371 Date: Oct. 5, 2022

(30) Foreign Application Priority Data
May 28, 2020 (JP) 2020-093581

(51) Int. Cl. C04B 35/01; H01J 37/32; H01L 21/683; C04B 41/00; C04B 35/64

(52) U.S. Cl. CPC C04B 35/01; H01J 37/32715; H01L 21/6833; C04B 41/0072; C04B 35/64; C04B 2235/3217; C04B 2235/3232; C04B 2235/3821; C04B 2235/96

(57) ABSTRACT

Provided is a dielectric for an electrostatic chuck, which is capable of ensuring sufficient hardness, while ensuring basic properties, such as intrinsic volume resistivity, required for a dielectric for a Johnson-Rahbek type electrostatic chuck. The dielectric has a main crystal phase consisting of corundum, wherein the dielectric includes Al₅BO₉ as another crystal phase, and wherein a ratio I_{A}/I_{B}, where I_{A} denotes a (021) peak intensity of Al₅BO₉ as measured by powder X-ray diffraction, and I_{B} denotes a (012) peak intensity of corundum as measured by powder X-ray diffraction, is in the range of 0.04 to 0.4.

### TECHNICAL FIELD

The present invention relates to a dielectric used for an electrostatic chuck configured to highly accurately position and secure any of various substrates including semiconductor wafers such as a silicon wafer, and LCD glass substrates.

### BACKGROUND ART

For example, in order to subject a silicon wafer to film formation, lithographic exposure, etching, etc., in a semiconductor manufacturing apparatus, for the purpose of forming a circuit on the silicon wafer, it is necessary to hold the target wafer in such a manner as to maintain flatness of the wafer and prevent the occurrence of an uneven temperature distribution on the wafer. As such wafer holding means, a mechanical system, a vacuum chucking system and an electrostatic chucking system have been proposed. Among these holding means, the electrostatic chucking system is configured to hold a wafer by an electrostatic chuck and can be used in a vacuum atmosphere, so that it is widely used.

There are two types of electrostatic chucks: one type which utilizes Coulomb force as chucking force (Coulomb type); and the other type which utilizes Johnson-Rahbek force as chucking force (Johnson-Rahbek type). The Johnson-Rahbek force of the latter is a force induced by a charge polarization occurring when a minute electric current flows across a small gap at an interface between a dielectric and a wafer. The Johnson-Rahbek force is generated when the dielectric has an intrinsic volume resistivity of 10¹² to 10¹³ Ω·cm. Further, in order to ensure an chucking force necessary as an electrostatic chuck by using the Johnson-Rahbek force, the requirement for it is that the intrinsic volume resistivity of the dielectric falls within the range of 10⁹ to 10¹² Ω·cm.

Heretofore, as a dielectric for a Johnson-Rahbek type electrostatic chuck, there has been known a ceramic in which a transition metal element is added to alumina, such as Al₂O₃—TiO₂ based dielectric (see, for example, the following Patent Document 1).

### CITATION LIST

### Patent Document

Patent Document 1: JP-B 4354138

### SUMMARY OF INVENTION

### Technical Problem

The present inventors checked the practicality of the Al₂O₃—TiO₂ based dielectric disclosed in the Patent Document 1 by using it in an electrostatic chuck of an etching apparatus. As a result, it has been found that the durability of the dielectric is not sufficient. Specifically, it has been found that, when the electrostatic chuck is used in the etching apparatus under a plasma atmosphere, the Al₂O₃—TiO₂ based dielectric disclosed in the Patent Document 1 deteriorates in terms of plasma resistance due to insufficient hardness thereof, resulting in failing to obtain sufficient durability.

Therefore, a technical problem to be solved by the present invention is to provide a dielectric for an electrostatic chuck, capable of ensuring sufficient hardness, while ensuring basic properties, such as intrinsic volume resistivity, required for a dielectric for a Johnson-Rahbek type electrostatic chuck.

### Solution to Technical Problem

As a result of repeated experimental tests and studies conducted by the present inventors so as to solve the above technical problem, it has been found that a dielectric for an electrostatic chuck, having a main crystal phase consisting of corundum, can ensure sufficient hardness, while ensuring basic properties, such as intrinsic volume resistivity, required for a dielectric for a Johnson-Rahbek type electrostatic chuck, by including an appropriate amount of Al₅BO₉ in the dielectric as another crystal phase.

Specifically, the present invention provides a dielectric for an electrostatic chuck, having the following features described in sections 1 to 3.

1. A dielectric for an electrostatic chuck, having a main crystal phase consisting of corundum, wherein the dielectric includes Al₅BO₉ as another crystal phase, and wherein a ratio I_{A}/I_{B}, where I_{A} denotes a (021) peak intensity of Al₅BO₉ as measured by powder X-ray diffraction, and I_{B} denotes a (012) peak intensity of corundum as measured by powder X-ray diffraction, is in the range of 0.04 to 0.4.
2. The dielectric as set forth in the section 1, having a Vickers hardness of 16 GPa or more.
3. The dielectric as set forth in the section 1 or 2, obtained by subjecting a composition containing 0.8% by mass to 3% by mass of titania, and 0.2% by mass to 1% by mass of boron carbide, with a remainder consisting mainly of an alumina raw material, to mixing, forming and sintering.

### Effect of Invention

The present invention can ensure sufficient hardness, while ensuring basic properties, such as intrinsic volume resistivity, required for a dielectric for a Johnson-Rahbek type electrostatic chuck.

### BRIEF DESCRIPTION OF DRAWINGS

FIG. 1 is a chart showing powder X-ray diffraction intensity data in Example 1 which is an example of the present invention.

FIG. 2 is a conceptual sectional view of one example of a Johnson-Rahbek type electrostatic chuck.

### DESCRIPTION OF EMBODIMENTS

A dielectric for an electrostatic chuck, of the present invention, has a main crystal phase consisting of corundum, wherein the dielectric includes Al₅BO₉ as another crystal phase, and wherein a peak intensity ratio I_{A}/I_{B}, where I_{A} denotes a (021) peak intensity of Al₅BO₉ as measured by powder X-ray diffraction, and I_{B} denotes a (012) peak intensity of corundum as measured by powder X-ray diffraction, is in the range of 0.04 to 0.4.

If the ratio I_{A}/I_{B} is less than 0.04, it becomes impossible to ensure sufficient hardness.

On the other hand, if the ratio I_{A}/I_{B} is greater than 0.4, a large amount of Al₅BO₉ is produced in grain boundaries, which causes an increase in intrinsic volume resistivity and a decrease in chucking force. Specifically, in a dielectric for a Johnson-Rahbek type electrostatic chuck, a low-resistance grain boundary phase is formed in grain boundaries to ensure moderate conductivity and reduce the intrinsic volume resistivity. However, if a large amount of Al₅BO₉ is produced in grain boundaries, the Al₅BO₉ impairs the conductivity of the low-resistance grain boundary phase, resulting in increased intrinsic volume resistivity.

The hardness of the dielectric of the present invention may be 16 GPa or more in terms of Vickers hardness. That is, “16 GPa or more in terms of Vickers hardness” is one indication that sufficient hardness is ensured. From a viewpoint of ensuring more sufficient hardness, the hardness of the dielectric of the present invention may be 18 GPa or more in terms of Vickers hardness. In order to ensure a Vickers hardness of 18 GPa or more, the ratio I_{A}/I_{B} is preferably set to 0.18 to 0.4.

Such a dielectric of the present invention can be produced by subjecting a composition containing 0.8% by mass to 3% by mass of titania, and 0.2% by mass to 1% by mass of boron carbide, with a remainder consisting mainly of an alumina raw material, to mixing, forming and sintering.

If the content rate of titania in the composition is less than 0.8% by mass, the amount of production of Ti³⁺ is reduced, leading to concerns about an increase in the intrinsic volume resistivity and a decrease in the chucking force. Specifically, titania (TiO₂) is solid-solved in a grain boundary phase of alumina (Al₂O₃) raw material particles, causing a decrease in the intrinsic volume resistivity. More specifically, during sintering, a part of Ti⁴⁺ of TiO₂ is reduced to Ti³⁺, and this Ti³⁺ is substitutionally solid-solved in an Al′ site of Al₂O₃, thereby forming a low-resistance grain boundary phase ((Al, Ti)₂O₃). Thus, if the content rate of titania in the composition is less than 0.8% by mass, the amount of production of Ti³⁺ is reduced, leading to concerns about an increase in the intrinsic volume resistivity and a decrease in the chucking force.

On the other hand, if the content rate of titania in the composition is greater than 3% by mass, there is concern that the intrinsic volume resistivity is excessively reduced and thus leakage current becomes large, which exerts a harmful influence on circuitry on a wafer, etc.,

If the content rate of boron carbide (B₄C) in the composition is less than 0.2% by mass, there is concern that it becomes impossible to ensure sufficient hardness. Particularly, in a case where the electrostatic chuck is used under a plasma atmosphere, failure to ensure sufficient hardness is likely to accelerate degradation and reduce durability. Further, if the content rate of boron carbide in the composition is less than 0.2% by mass, blackening of the electrostatic chuck becomes insufficient, stains are likely to become more noticeable.

On the other hand, if the content rate of boron carbide in the composition is greater than 1% by mass, a large amount of Al₅BO₉ is produced in grain boundaries, leading to concerns about an increase in the intrinsic volume resistivity and a decrease in the chucking force.

From a viewpoint of ensuring more sufficient hardness, the content rate of boron carbide in the composition is preferably set to 0.4% by mass to 1% by mass.

The dielectric of the present invention is obtained by: mixing together titania, boron carbide and an alumina raw material each weighted in the given amount as mentioned above; forming the resulting mixture into a given shape by means of press forming, CIP (Cold Isostatic Press), doctor blade forming, etc.; subjecting the resulting shaped body to degreasing, if needed; and then subjecting the shaped body to sintering.

Although the sintering may be performed by pressureless sintering, the resulting sintered body tends to have a relatively low density. Thus, it is desirable to perform pressure sintering, such as hot press, HIP (Hot Isostatic Pressing), or gas-pressure sintering. A sintering atmosphere may be an inert gas atmosphere such as an argon atmosphere, a reducing gas atmosphere (i.e., non-oxidizing atmosphere) such as a hydrogen atmosphere, or a vacuum atmosphere. A sintering temperature may be set to 1200° C. to 1700° C.

In the composition used in the present invention, the remainder, i.e., a part other than titania and boron carbide, consists mainly of an alumina raw material. However, in addition to the alumina raw material, the remainder may include, as a sintering aid, magnesium oxide (MgO), silica (SiO₂), lanthanum oxide (La₂O₃), yttrium oxide (Y₂O₃), calcium oxide (CaO), and/or cerium oxide (Ce₂O₃). In this case, the content rate of one or more of the sintering aids is preferably set to 3% by mass or less (including 0) in total.

### Examples

Titania, boron carbide and an alumina raw material were blended such that they are contained in respective content rate s of each example as shown in Table 1, thereby obtaining a composition, and the composition in each example was subjected to mixing, forming and sintering, thereby obtaining a dielectric for an electrostatic chuck, with respect to each example.

With regard to the obtained dielectric in each example, the ratio I_{A}/I_{B}, where I_{A} denotes a (021) peak intensity of Al₅BO₉ as measured by powder X-ray diffraction by using Cu—K α ray, and I_{B} denotes a (012) peak intensity of corundum as measured by powder X-ray diffraction by using Cu—K α ray, was evaluated, and the Vickers hardness, intrinsic volume resistivity and chucking force were evaluated. In addition, judgment about color tone was performed.

TABLE 1

| | Exam- | Exam- | Exam- | Exam- | Exam- | Exam- | Exam- | Comparative | Comparative |
|---|---|---|---|---|---|---|---|---|---|
| | ple1 | ple2 | ple3 | ple4 | ple5 | ple6 | ple7 | Example 1 | Example 2 |
| Titania (% by mass) | 1.2 | 0.8 | 1 | 3 | 1.2 | 1.2 | 1.5 | 1.2 | 1.2 |
| Boron carbide | 0.4 | 0.2 | 0.4 | 0.4 | 0.2 | 1 | 0.5 | 0 | 2 |
| (% by mass) | | | | | | | | | |
| Alumina raw material | 98.4 | 99 | 98.6 | 96.6 | 98.6 | 97.8 | 98 | 98.8 | 96.8 |
| (% by mass) | | | | | | | | | |
| Peak intensity ratio I_{A}/I_{B} | 0.20 | 0.06 | 0.21 | 0.18 | 0.04 | 0.40 | 0.25 | — | 0.65 |
| Vickers hardness | ⊚ | ◯ | ⊚ | ⊚ | ◯ | ⊚ | ⊚ | X | ⊚ |
| Intrinsic volume resistivit | ⊚ | O(H) | ⊚ | O(L) | ⊚ | O(H) | ⊚ | ⊚ | X (H) |
| Chucking force | ⊚ | ⊚ | ⊚ | ◯ | ⊚ | ⊚ | ⊚ | ⊚ | X |
| Color tone judgment | Black | Indigo | Black | Black | Indigo | Black | Black | Blue | Black |
| | | blu | | | blue | | | | |

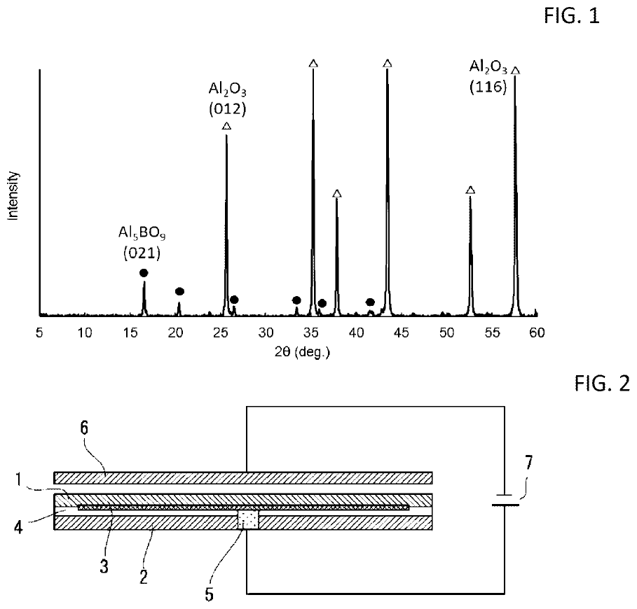

In FIG. 1, powder X-ray diffraction intensity data in Example 1 which is an example of the present invention is shown as one example of powder X-ray diffraction. The ratio I_{A}/I_{B}, where I_{A} denotes the (021) peak intensity of Al₅BO₉ and I_{B} denotes the (012) peak intensity of corundum, was evaluated based on the above powder X-ray diffraction intensity data. Here, the peak intensity ratio I_{A}/In in each example was adjusted mainly by adjusting the content rate of boron carbide in the composition in each example.

The Vickers hardness was measured in accordance with JIS Z2244 (pressing force: 1 kgf). A dielectric having a Vickers hardness of 18 GPa or more, a dielectric having a Vickers hardness of 16 GPa to less than 18 GPa, and a dielectric having a Vickers hardness of less than 16 GPa, were evaluated, respectively, as ⊚ (excellent), ∘ (Good), and x (NG).

The intrinsic volume resistivity was measured by a three terminal method (applied voltage: 500V, room temperature). A dielectric having an intrinsic volume resistivity of 9.7×10⁹ Ω·cm to 3.8×10¹⁰ Ω·cm, a dielectric having an intrinsic volume resistivity of greater 3.8×10¹⁰ Ω·cm to 1.3×10¹¹ Ω·cm or of 3.8×10⁹ Ω·cm to less than 9.7×10⁹ Ω·cm, and a dielectric having an intrinsic volume resistivity of greater than 1.3×10¹¹ Ω·cm or of less than 3.8×10⁹ Ω·cm, were evaluated, respectively, as ⊚ (excellent), ∘ (Good), and x (NG).

In Table 1, among dielectrics evaluated as ∘ (Good), one type of dielectric having an intrinsic volume resistivity of greater 3.8×10¹⁰ Ω·cm to 1.3×10¹¹ Ω·cm is expressed as ∘ (H), and another type of dielectric having an intrinsic volume resistivity of 3.8×10⁹ Ω·cm to less than 9.7×10⁹ Ω·cm is expressed as ∘ (L). Further, among dielectrics evaluated as x (NG), one type of dielectric having an intrinsic volume resistivity of greater than 1.3×10¹¹ Ω·cm is expressed as x (H), and another type of dielectric having an intrinsic volume resistivity of less than 3.8×10⁹ Ω·cm is expressed as x (L).

The chucking force was measured under the condition that the dielectric in each example was incorporated in a Johnson-Rahbek type electrostatic chuck as shown in FIG. 2. Specifically, as shown in FIG. 2, Ti was sputtered onto one of opposite surfaces of the dielectric 1 to give an electrode as a conductive layer 3. Then, an insulator substrate 2 (alumina) was bonded to the one surface of the dielectric 1 with an epoxy adhesive such that the conductive layer 3 is sandwiched therebetween. Then, the dielectric 1 was subjected to grinding until it had a thickness of 2 mm and then to lapping, and a lead electrode 5 was finally attached to a through-hole preliminarily formed at the center of the insulator substrate 2, to prepare an electrostatic chuck. The chucking force was measured under the condition that a 300V DC voltage was applied from a power supply 7 to the electrostatic chuck in a vacuum for 60 seconds to electrostatically attract a silicon wafer 6 in a vacuum. An electrostatic chuck having an chucking force of 40 g/cm² or more, an electrostatic chuck having an chucking force of 20 g/cm² to less than 40 g/cm², and an electrostatic chuck having an chucking force of less than 20 g/cm², were evaluated, respectively, as ⊚ (excellent), ∘ (Good), and x (NG).

The judgment about color tone was visually performed.

In Table 1, Examples 1-7 are dielectrics each falling within the scope of the present invention defined in the appended claims, wherein each result of the above evaluations was ⊚ (excellent) or ∘ (Good), and the result of the color tone judgment was black or indigo blue. Among them, in Examples 1, 3, 4, 6 and 7 whose peak intensity ratio (I_{A}/I_{B}) is in the range of 0.18 to 0.4, the Vickers hardness was 18 GPa or more (CD (excellent)), i.e., particularly good, and the result of the color tone judgment was block, i.e., also particularly good.

On the other hand, in Comparative Example 1 which is an example whose peak intensity ratio (I_{A}/I_{B}) is excessively small, the Vickers hardness was less than 16 GPa (× (NG)), i.e., sufficient hardness could not be obtained. Moreover, the result of the color tone judgment was blue, i.e., also NG.

Further, in Comparative Example 2 which is an example whose peak intensity ratio (I_{A}/I_{B}) is excessively large, the intrinsic volume resistivity increased to greater than 1.3×10¹¹ Ω·cm, and thus the chucking force decreased.

### LIST OF REFERENCE SIGNS

1: dielectric
2: insulator substrate
3: conductive layer (electrode)
4: epoxy adhesive
5: lead electrode
6: silicon wafer
7: power supply

1. A dielectric for an electrostatic chuck, having a main crystal phase consisting of corundum, wherein the dielectric includes Al₅BO₉ as another crystal phase, and wherein a ratio I_{A}/I_{B}, where I_{A} denotes a (021) peak intensity of Al₅BO₉ as measured by powder X-ray diffraction, and I_{B} denotes a (012) peak intensity of corundum as measured by powder X-ray diffraction, is in the range of 0.04 to 0.4.

2. The dielectric as claimed in claim 1, having a Vickers hardness of 16 GPa or more.

3. The dielectric as claimed in claim 1, obtained by subjecting a composition containing 0.8% by mass to 3% by mass of titania, and 0.2% by mass to 1% by mass of boron carbide, with a remainder consisting mainly of an alumina raw material, to mixing, forming and sintering.

4. The dielectric as claimed in claim 2, obtained by subjecting a composition containing 0.8% by mass to 3% by mass of titania, and 0.2% by mass to 1% by mass of boron carbide, with a remainder consisting mainly of an alumina raw material, to mixing, forming and sintering.
